(19) United States
(12) Patent Application Publication
(10) Pub. No.: US 2025/0280648 A1
(43) Pub. Date: Sep. 4, 2025

(54) TANDEM HYBRID SOLAR CELL

(71) Applicants: Universal Display Corporation, Ewing, NJ (US); The Regents of the University of Michigan, Ann Arbor, MI (US)

(72) Inventors: Michael Hack, Carmel, CA (US); Stephen R. Forrest, Ann Arbor, MI (US); Hafiz K.M. Sheriff, Ann Arbor, MI (US)

(21) Appl. No.: 19/063,266

(22) Filed: Feb. 25, 2025

Related U.S. Application Data
(60) Provisional application No. 63/559,488, filed on Feb. 29, 2024.

(51) Int. Cl. H10K 30/57; H10K 30/35; H10K 30/40; H10K 71/16; H10K 77/10

(52) U.S. Cl. CPC H10K 30/57; H10K 30/35; H10K 77/111; H10K 30/40; H10K 71/164

(57) ABSTRACT

A tandem photovoltaic (PV) device comprises a substrate, a reflector layer on one side of the substrate, a first PV sub-cell in optical communication with the reflector layer configured to absorb visible light; and a second PV sub-cell above the first PV sub-cell configured to absorb NIR light.

### CROSS-REFERENCE TO RELATED APPLICATIONS

This application claims priority to U.S. provisional application No. 63/559,488 filed on Feb. 29, 2024, incorporated herein by reference in its entirety.

### BACKGROUND OF THE INVENTION

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

Photosensitive optoelectronic devices convert electromagnetic radiation into electricity. Solar cells, also called photovoltaic (PV) devices or cells, are a type of photosensitive optoelectronic device that is specifically used to generate electrical power. PV devices, which may generate electrical energy from light sources other than sunlight, may be used to drive power consuming loads to provide, for example, lighting, heating, or to power electronic circuitry or devices such as calculators, radios, computers or remote monitoring or communications equipment. These power generation applications may involve the charging of batteries or other energy storage devices so that operation may continue when direct illumination from the sun or other light sources is not available, or to balance the power output of the PV device with the specific applications requirements.

Traditionally, photosensitive optoelectronic devices have been constructed of a number of inorganic semiconductors, e.g., crystalline, polycrystalline and amorphous silicon, gallium arsenide, cadmium telluride, and others.

More recent efforts have focused on the use of organic photovoltaic (OPV) cells to achieve acceptable photovoltaic conversion efficiencies with economical production costs. OPVs offer a low-cost, light-weight, and mechanically flexible route to solar energy conversion. Compared with polymers, small molecule OPVs share the advantage of using materials with well-defined molecular structures and weights. This leads to a reliable pathway for purification and the ability to deposit multiple layers using highly controlled thermal deposition without concern for dissolving, and thus damaging, previously deposited layers or sub-cells. The use of tandem solar cells can lead to higher efficiency devices as each part of the tandem device can be designed to absorb different wavelengths of light so the overall device can capture more of the incident light, or if used outdoors, more of the solar spectrum.

### SUMMARY OF THE INVENTION

Some embodiments of the invention disclosed herein are set forth below, and any combination of these embodiments (or portions thereof) may be made to define another embodiment.

In one aspect, a tandem photovoltaic (PV) device, comprises: a substrate; a reflector layer above the substrate; a first PV sub-cell in optical communication with the reflector layer, configured to absorb visible light; and a second PV sub-cell above the first PV sub-cell, configured to absorb NIR light.

In one embodiment, the first PV sub-cell comprises a perovskite sub-cell.

In one embodiment, the first PV sub-cell comprises a CdTe sub-cell.

In one embodiment, the first PV sub-cell comprises a Si sub-cell, a CdSeTe sub-cell, or a CIGS sub-cell.

In one embodiment, the second PV sub-cell comprises an organic sub-cell.

In one embodiment, the device further comprises a charge generation layer (CGL) between the first and second PV sub-cells.

In one embodiment, the CGL comprises Ag nanoparticles.

In one embodiment, the device has a power conversion efficiency (PCE) greater than 30% or greater than 35%.

In one embodiment, the device comprises vacuum thermal evaporation (VTE) deposited films.

In one embodiment, the device comprises solution processed films.

In one embodiment, the first PV sub-cell comprises two or more PV sub-cells.

In one embodiment, the second PV sub-cell comprises two or more PV sub-cells.

In one embodiment, the second PV sub-cell is transparent or semi-transparent across the visible spectrum.

In one embodiment, the device comprises a two terminal (2T), a three terminal (3T), or a four terminal (4T) device.

In one embodiment, the device is flexible.

In one embodiment, the reflector layer is configured to reflect NIR light or visible light.

In another aspect, a product comprises the device as described above, wherein the product is selected from the group consisting of: a display screen, a discrete light source, a lighting panel, a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video wall comprising multiple displays tiled together, a theater or stadium screen, a sign, an electronic component module, a lighting panel, a solar cell, a light weight solar cell, a flexible solar cell, a solar cells integrated with thin film electronics, a thin film power supply, a solar farm, a sensor, a radio receiver/transmitter, an audio producing device, a computing device, an IT device, a shelf label, a window, a wall, and a roof.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIG. 1 shows an organic light emitting device.

FIG. 2 shows an inverted organic light emitting device that does not have a separate electron transport layer.

FIG. 3 shows a schematic diagram of preferred embodiment for a tandem OPV-perovskite (or CdTe) tandem solar cell allowing for efficient spectrum splitting and the ability of the NIR absorbing OPV device to be fabricated after the perovskite sub-cell and transmit visible light through to the back cell.

FIG. 4 shows details of a simulation of an organic front cell.

FIG. 5 shows details of a simulation of an inorganic back cell.

FIG. 6 shows an example device design.

FIG. 7 shows an example device design.

FIG. 8 shows details of a simulation of a hybrid PV device.

### DETAILED DESCRIPTION

It is to be understood that the figures and descriptions of the present invention have been simplified to illustrate elements that are relevant for a clear understanding of the present invention, while eliminating, for the purpose of clarity, many other elements found in related systems and methods. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, exemplary methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, and ±0.1% from the specified value, as such variations are appropriate.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, 6 and any whole and partial increments therebetween. This applies regardless of the breadth of the range.

As used herein, the terms “electrode” and “contact” may refer to a layer that provides a medium for delivering photo-generated current to an external circuit or providing a bias current or voltage to the device. That is, an electrode, or contact, provides the interface between the active regions of an organic photosensitive optoelectronic device and a wire, lead, trace or other means for transporting the charge carriers to or from the external circuit. Examples of electrodes include anodes and cathodes, which may be used in a photosensitive optoelectronic device.

As used herein, the term “transparent” may refer to an electrode that permits at least 50% of the incident electromagnetic radiation in relevant wavelengths to be transmitted through it. In a photosensitive optoelectronic device, it may be desirable to allow the maximum amount of ambient electromagnetic radiation from the device exterior to be admitted to the photoconductive active interior region. That is, the electromagnetic radiation must reach a photoconductive layer(s), where it can be converted to electricity by photoconductive absorption. This often dictates that at least one of the electrical contacts should be minimally absorbing and minimally reflecting of the incident electromagnetic radiation. In some cases, such a contact should be transparent or at least semi-transparent.

As used herein, the term “semi-transparent” may refer to an electrode that permits some, but less than 50% transmission of ambient electromagnetic radiation in relevant wavelengths. The opposing electrode may be a reflective material so that light which has passed through the cell without being absorbed is reflected back through the cell.

As used and depicted herein, a “layer” refers to a member or component of a photosensitive device whose primary dimension is X-Y, i.e., along its length and width. It should be understood that the term layer is not necessarily limited to single layers or sheets of materials. In addition, it should be understood that the surfaces of certain layers, including the interface(s) of such layers with other material(s) or layers(s), may be imperfect, wherein said surfaces represent an interpenetrating, entangled or convoluted network with other material(s) or layer(s). Similarly, it should also be understood that a layer may be discontinuous, such that the continuity of said layer along the X-Y dimension may be disturbed or otherwise interrupted by other layer(s) or material(s).

As used herein, a “photoactive region” refers to a region of the device that absorbs electromagnetic radiation to generate excitons. Similarly, a layer is “photoactive” if it absorbs electromagnetic radiation to generate excitons. The excitons may dissociate into an electron and a hole in order to generate an electrical current.

As used herein, the terms “donor” and “acceptor” refer to the relative positions of the highest occupied molecular orbital (“HOMO”) and lowest unoccupied molecular orbital (“LUMO”) energy levels of two contacting but different organic materials. If the LUMO energy level of one material in contact with another is lower, then that material is an acceptor. Otherwise it is a donor. It is energetically favorable, in the absence of an external bias, for electrons at a donor-acceptor junction to move into the acceptor material, and for holes to move into the donor material.

As used herein, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Because ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, the term “band gap” (E_{g}) of a polymer may refer to the energy difference between the HOMO and the LUMO. The band gap is typically reported in electronvolts (eV). The band gap may be measured from the UV-vis spectroscopy or cyclic voltammetry. A “low band gap” polymer may refer to a polymer with a band gap below 2 eV, e.g., the polymer absorbs light with wavelengths longer than 620 nm.

As used herein, the term “excitation binding energy” (E_{B}) may refer to the following formula: E_{B}=(M⁺+M⁻)−(M*+M), where M⁺ and M⁻ are the total energy of a positively and negatively charged molecule, respectively; M* and M are the molecular energy at the first singlet state (S₁) and ground state, respectively. Excitation binding energy of acceptor or donor molecules affects the energy offset needed for efficient exciton dissociation. In certain examples, the escape yield of a hole increases as the HOMO offset increases. A decrease of exciton binding energy E_{B} for the acceptor molecule leads to an increase of hole escape yield for the same HOMO offset between donor and acceptor molecules.

As used herein, power conversion efficiency (η_{ρ}) may be expressed as:

$${η}_{ρ} = \frac{{V}_{OC} * FF * {J}_{SC}}{{P}_{O}}$$

wherein V_{OC} is the open circuit voltage, FF is the fill factor, J_{SC} is the short circuit current, and P_{O} is the input optical power.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which comprises a series of chemical shells built on the core moiety. A dendrimer may be a “small molecule,” and it is believed that all dendrimers currently used in the field of organic optoelectronic devices are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of a material. A ligand may be referred to as “ancillary” when it is believed that the ligand does not contribute to the photoactive properties of a material, although an ancillary ligand may alter the properties of a photoactive ligand.

As used herein, and as would be generally understood by one skilled in the art, on a conventional energy level diagram, with the vacuum level at the top, a “shallower” energy level appears higher, or closer to the top, of such a diagram than a “deeper” energy level, which appears lower, or closer to the bottom.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution-based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJP. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present disclosure may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material comprises essentially of polymeric silicon and inorganic silicon.

Although certain embodiments of the disclosure are discussed in relation to one particular device or type of device (for example OPVs) it is understood that the disclosed improvements may be equally applied to other devices, including but not limited to OLEDs, PLEDs, charge-coupled devices (CCDs), photosensors, or the like.

Although exemplary embodiments described herein may be presented as methods for producing particular circuits or devices, for example OPVs, it is understood that the materials and structures described herein may have applications in devices other than OPVs. For example, other optoelectronic devices such as OLEDs and organic photodetectors may employ the materials and structures. More generally, organic devices, such as organic transistors, or other organic electronic circuits or components, may employ the materials and structures.

In some embodiments, the optoelectronic device has one or more characteristics selected from the group consisting of being flexible, being rollable, being foldable, being stretchable, and being curved. In some embodiments, the optoelectronic device is transparent or semi-transparent. In some embodiments, the optoelectronic device further comprises a layer comprising carbon nanotubes.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OPV that includes the compound of the present disclosure in the organic layer in the OPV is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25° C.), but could be used outside this temperature range, for example, from −40 C to 80 C.

According to an embodiment, the devices fabricated in accordance with embodiments of the invention may be incorporated into one or more device selected from a consumer product, an electronic component module, a lighting panel, and/or a sign or display. Further examples of such electronic products or intermediate components include solar cells, light weight solar cells, flexible solar cells, solar cells integrated with thin film electronics including for power conversion and management, thin film power supply consisting of an OPV cell integrated with thin film electronics for power consumption and management, a solar farm including one or more OPV cells and/or devices that may be integrated in an array, solar farm including semi-transparent OPV cells and/or devices for advantages related to plants/crops, an OPV, device on a same substrate as a display, such as a thin film display, with integrated or external electronics, an OPV integrated with one or more sensors, including but not limited to mechanical, electrical and/or biological sensors, an OPV on a same substrate as a radio receive/transmitter, an OPV on a same substrate as an audio producing device, an OPV on the same substrate as a computing device, an OPV for powering IT devices, an OPV for powering shelf labels, an OPV for indoor applications, an OPV for integration with a window, wall, roof, etc., an OPV for use in a solar. In an embodiment, the OPV device may be fully or partially transparent, flexible, curved, rollable, foldable, or stretchable.

According to embodiments, the devices fabricated in accordance with embodiments of the invention may be incorporated with a battery on a same substrate as the device or connected to a battery on a different substrate/device. According to embodiments, the battery may be a standard battery and/or thin film battery.

According to embodiments, the devices fabricated may be a thin film OPV device. In an embodiment, a thin film device is one where the layers of the device are deposited as opposed to being placed on the substrate.

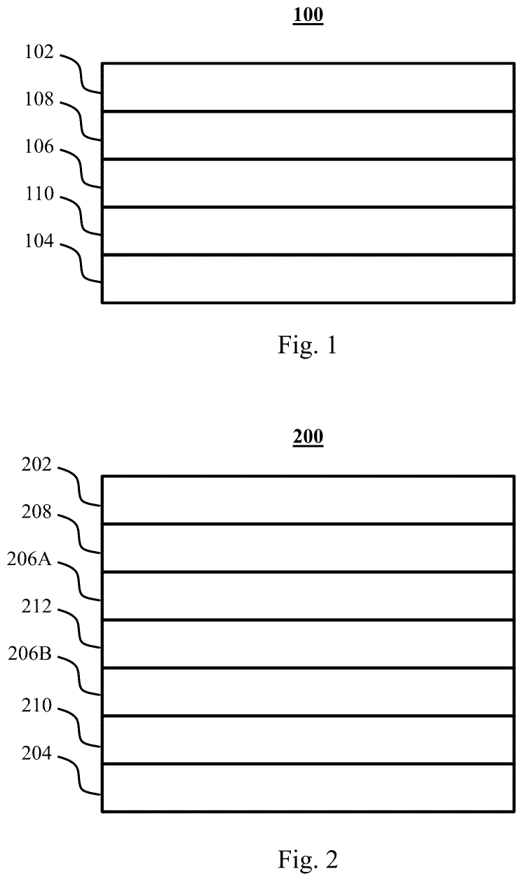

FIG. 1 depicts an example of various layers of a single-junction solar cell or organic photovoltaic (OPV) cell 100. The exemplary OPV 100 includes an anode 102, cathode 104, active layer 106, intermediate layer 108, and another intermediate layer 110.

The OPV cell may include two electrodes having an anode 102 and a cathode 104 in superposed relation, at least one donor composition, and at least one acceptor composition, wherein the donor-acceptor material or active layer 106 is positioned between the two electrodes 102, 104. In some embodiments, active layer 106 may be an organic heterojunction, as explained below. In some embodiments, at least one intermediate layer 108 may be positioned between the anode 102 and the active layer 106. Additionally, or alternatively, at least one intermediate layer 110 may be positioned between the active layer 106 and cathode 104.

Still referring to FIG. 1, the anode 102 may include a conducting oxide, thin metal layer, or conducting polymer. In some examples, the anode 102 includes a (e.g., transparent) conductive metal oxide such as indium tin oxide (ITO), tin oxide (TO), gallium indium tin oxide (GITO), zinc oxide (ZO), or zinc indium tin oxide (ZITO). In other examples, the anode 102 includes a thin metal layer, wherein the metal is selected from the group consisting of Ag, Au, Pd, Pt, Ti, V, Zn, Sn, Al, Co, Ni, Cu, Cr, or combinations thereof. In yet other examples, the anode 102 includes a (e.g., transparent) conductive polymer such as polyanaline (PANI), or 3,4-polyethylenedioxythiophene:polystyrenesulfonate (PEDOT:PSS). The thickness of the anode 102 may be 0.1-100 nm, 1-10 nm, 0.1-10 nm, or 10-100 nm.

Continuing to refer to FIG. 1, the cathode 104 may be a conducting oxide, thin metal layer, or conducting polymer similar or different from the materials discussed above for the anode 102. In certain examples, the cathode 104 may include a metal or metal alloy. The cathode 104 may include Ca, Al, Mg, Ti, W, Ag, Au, or another appropriate metal, or an alloy thereof. The thickness of the cathode 104 may be 0.1-100 nm, 1-10 nm, 0.1-10 nm, or 10-100 nm.

In some embodiments, the optoelectronic device additionally comprises a flexible plastic substrate as one of its layers. A flexible plastic substrate, as used herein, is defined as a bottom layer component of a solar cell. The substrate may protect the backside of the optoelectronic device from the effects of weather conditions and may mitigate any electric shock hazards, such as different environmental conditions like moisture, UV exposure and other performance threats. The substrate may further comprise of multiple layers of adhesives, barrier films, and/or polymers. The flexible plastic substrate may have any properties of any of the substrates described previously herein. In some embodiments, the flexible plastic substrate may be positioned under the active layer 106 or organic heterojunction. In some embodiments, the flexible plastic substrate comprises plastic, glass, or other suitable materials, such as a material that is transparent to at least a portion of the emissive spectrum of the OPV. The thickness of the flexible plastic substrate may be in the range of 10-100 μm.

In some embodiments, the optoelectronic device further comprises a coating or barrier layer over the flexible plastic substrate. The anode 102 and a cathode 104 are positioned over the coating. One purpose of the coating over the flexible plastic substrate is to protect the electrodes and organic layers of the OPV from damaging exposure to harmful species in the environment including moisture, vapor and/or gases, etc. The coating may be deposited over, under or next to a substrate, an electrode, or over any other parts of a device including an edge. The coating may comprise a single layer, or multiple layers. The coating may be formed by various known chemical vapor deposition techniques and may include compositions having a single phase as well as compositions having multiple phases. Any suitable material or combination of materials may be used for the coating. The coating may comprise a glass or a polymer. The coating may incorporate an inorganic or an organic compound or both. An exemplary coating comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material comprises of polymeric silicon and inorganic silicon.

As noted above, in some embodiments, the OPV may include one or more intermediate layers, for example charge collecting and transporting intermediate layers positioned between anode 102, cathode 104 and the active region or layer 106. The intermediate layer 108, 110 may be a metal oxide. In certain examples, the intermediate layer 108, 110 includes MoO₃, V₂O₅, ZnO, or TiO₂. In some examples, the first intermediate layer 108 has a similar composition to the second intermediate layer 110. In other examples, the first and second intermediate layers 108, 110 have different compositions. The thickness of each intermediate layer may be 0.1-100 nm, 1-10 nm, 0.1-10 nm, or 10-100 nm.

In some embodiments, the active region or layer 106 positioned between the electrodes 102, 104 includes a composition or molecule having an acceptor and a donor. In an embodiment, the optoelectronic device described herein has an organic heterojunction positioned between the anode 102 and the cathode 104 among the active layer 106. The organic heterojunction has a donor, or donor material, and an acceptor, or acceptor material. In some embodiments, the composition may be arranged as an acceptor-donor-acceptor (A-D-A).

In some embodiments, the device includes an encapsulating layer positioned over the anode 102 and the cathode 104. The encapsulating layer may have any of the same properties of or be made of the same materials as the coating described above. The encapsulating layer may comprise a single layer, or multiple layers. The encapsulating layer may be formed by various known chemical vapor deposition techniques and may include compositions having a single phase as well as compositions having multiple phases. Any suitable material or combination of materials may be used for the encapsulating layer. The encapsulating layer may comprise a glass or a polymer. The encapsulating layer may incorporate an inorganic or an organic compound or both. The preferred encapsulating layer may comprise a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. In one example, the mixture of a polymeric material and a non-polymeric material comprising polymeric silicon and/or inorganic silicon.

The encapsulating layer may in some embodiments be the outermost layer of the flexible optoelectronic device and may be configured to help protect the inner layers, including the cathode and anode, from environmental or other external conditions. In an embodiment, the encapsulating layer may surround the entirety of the flexible optoelectronic device or may additionally be provided with another protective layer on top of the encapsulating layer.

Furthermore, the encapsulating layer may comprise a multilayer, wherein the multilayer comprises a plurality of molecular dyads. As used herein, the term “molecular dyads” refers to pairs of layers of different materials. The multilayer of the plurality of dyads may help further enhance the protection provided by the encapsulating layer. In one embodiment, the multilayer of the plurality of dyads may comprise glass, or any other similar material. The multilayer may comprise any material described in relation to the coating described previously herein. The multilayer may incorporate an inorganic or an organic compound or both. The multilayer may comprise any number of layers of dyads, for example between 2 and 10 or between 3 and 8 between 4 and 6 dyads. In one embodiment, the multilayer of dyads may include three dyads. In another embodiment, the multilayer of dyads may include two dyads. Further, each dyad of the multilayer of dyads may have a specific thickness, which in some embodiments, may be in the range of 10-500 nm or between 10nm and 200 nm, or between 10 nm and 100 nm, or between 10 nm and 50 nm, or between 20 nm and 80 nm, or between 40 nm and 80 nm.

In some embodiments, the plurality of dyads in the multilayer may be separated by a polymer positioned between each dyad. The polymer may be any of a class of natural or synthetic substances composed of macromolecules that are multiples of monomers. The polymer may be any of the polymers as previously described herein or in referenced applications or publications. The polymer between each dyad may enable the maximum amount of light to shine through the device. Each polymer layer may have a thickness in the range of 1-10 μm.

Now referring to FIG. 2, depicted is an example of various layers of a tandem or multi-junction solar cell or organic photovoltaic (OPV) cell 200. The OPV cell may include two electrodes having an anode 202 and a cathode 204 in superposed relation, at least one donor composition, and at least one acceptor composition positioned within a plurality of active layers or regions 206A, 206B between the two electrodes 202, 204. While only two active layers or regions 206A, 206B are depicted in FIG. 2, additional active layers or regions may also be possible for the invention described herein. Anode 202 may share any of the same qualities or characteristics described above for anode 102. Cathode 204 may share any of the same qualities or characteristics described above for cathode 104. Plurality of active layers or regions 206A and 206B may share any of the same qualities or characteristics described above for active layer or region 106. At least one intermediate layer 208 may share any of the same qualities or characteristics described above for intermediate layers 108 and 110.

In one embodiment, at least one intermediate layer 208 may be positioned between the anode 202 and a first active layer 206A. Additionally, or alternatively, at least one intermediate layer 210 may be positioned between the second active layer 206B and cathode 204. Furthermore, in another embodiment, at least one intermediate layer 212 may be positioned between the first active layer 206A and the second active layer 206B. The compositions, thicknesses, etc. of each layer may be the same as those discussed with reference to FIG. 1.

In one embodiment, the plurality of active layers or regions 206A, 206B may include an organic heterojunction comprising the donor and acceptor materials. In another embodiment, the organic heterojunction may be its own organic layer or apart of any other organic layer, as long as it is positioned between the electrodes. The active region or layer 106, 206A, 206B positioned between the electrodes includes a composition or molecule having an acceptor and a donor. The composition may be arranged as an acceptor-donor-acceptor (A-D-A).

The OPV 200 may further include an encapsulating layer comprising a glass or a polymer, positioned over the anode and the cathode. The encapsulating layer may comprise of a multilayer of dyads, as explained previously. The multilayer of dyads may be separated by a polymer between each dyad.

The compositions, thicknesses, etc. of each layer may be the same as those discussed with reference to FIG. 1.

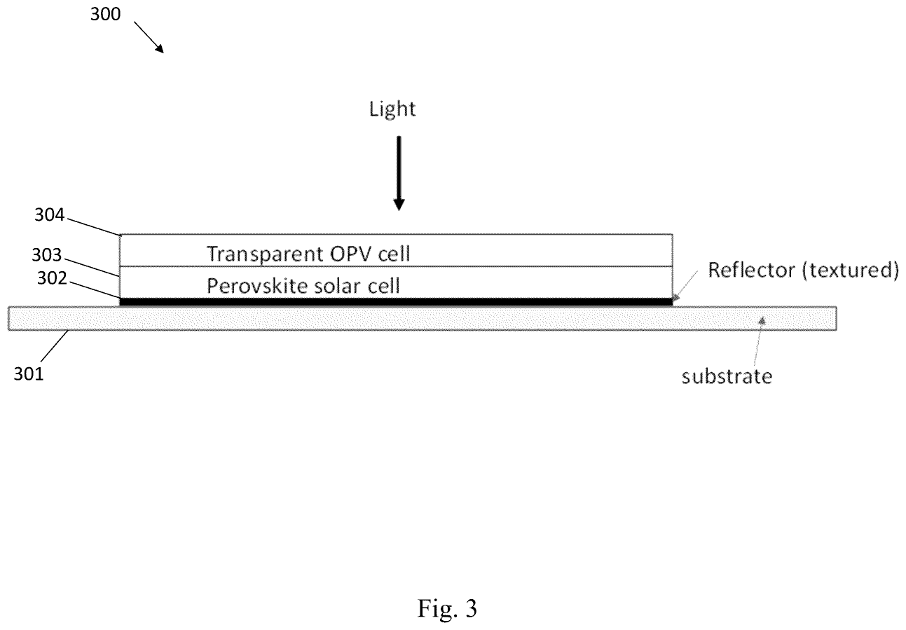

Referring now to FIG. 3, tandem solar cells are an ideal way to efficiently convert the solar spectrum into electrical energy. Each sub-cell within the overall tandem device can absorb a different portion of the incoming light or solar spectrum and so increase the current output of the device by absorbing more light and generating more electricity. Thin film approaches benefit from low cost, low temperature processing and low embedded energy in the manufacturing. Given the available material systems of perovskites, organics and CdTe, only organic materials can absorb well in the near infra-red. So a high efficiency tandem device can be made by combining two sub-cells; either an organic with a perovskite or or an organic with a CdTe. In one embodiment, an organic subcell may be combined with a CIGS (copper indium gallium selenide) subcell.

In one embodiment, a visible light absorbing subcell, such as a perovskite, CdTe, or CIGs subcell, may be configured to absorb light primarily in the 400 nm to 700 nm range, or the 350 nm to 750 nm range. In one embodiment, a NIR (near infra-red) absorbing subcell may be configured to absorb light in the range of 700 nm to 1000 nm, or 700 nm to 1200 nm, or 750 nm to 1000 nm, or 750 nm to 1200 nm. In some embodiments, a NIR absorbing subcell may also absorb some light in the visible spectrum for example in the 400 nm to 700 nm range, or in the 350 nm to 750 nm range.

In some embodiments, the device 300 comprises a substrate 301, a textured back reflector 302 over the substrate 301, a high energy absorbing cell 303 or multiple thereof and a low energy absorbing cell 304 facing the incident radiation. However, processing restrictions require the organic device to be the last or top sub-cell in the fabrication process thus implying that incident light will be absorbed in the red absorbing cell which is generally not advantageous from an efficiency viewpoint-as the red absorbing cell will usually have a lower open circuit voltage than a blue absorbing cell, so it is preferable to have blue light absorbed in a blue light absorbing cell and not a red light absorbing cell. To meet all these requirements the disclosed novel device comprises a stack where the light enters a semi-transparent OPV sub-cell 304 which absorbs the low energy (red and near infra-red) light and transmits the visible light to a higher energy perovskite, CdTe, or CIGS cell 303 placed below the transparent OPV sub-cell 304, thus closer to the back reflector 302, and away from the incident light. Hence, the OPV sub-cell will not absorb the visible light. Generally, the chemicals and processing (annealing) temperatures used to make the perovskite cell will damage the organic cell.

The device 300 requires integration of top and bottom cells. This integration can include direct electrical connections (e.g. via a 2-terminal device) or optical integration (e.g. via a 4-terminal device) where the two subcells may or may not physically touch one another. The electrical interconnection between the cells may be provided by an Ag nanoparticle layer sandwiched between an ETL and an HTL, one contacting the perovskite cell 303 and the other the organic 304, depending on which one has its cathode or anode facing the interface. This charge generation layer can use one of many different structures as described in previous patents or publications such as Forrest, Organic Electronics: Foundations to Applications, 2020, Sec. 7.5.2, incorporated herein by reference in its entirety.

A series connection requires current matching between the sub-cells (303, 304). In this case, the current of the sub-cells (303, 304) can be matched by varying the relative thicknesses of their active regions. Specific thicknesses of active regions may be chosen based on the specific materials used in each subcell, but suitable ranges may be for example 50 nm to 1000 nm, or 50 nm to 800 nm, or 50 nm to 600 nm, or 50 nm to 500 nm, or 50 nm to 400 nm, or 50 nm to 300 nm, or 50 nm to 200 nm, or 50 nm to 100 nm, or 200 nm to 1000 nm, or 300 nm to 1000 nm, or 400 nm to 1000 nm, or 500 nm to 1000 nm, or 500 nm to 1200 nm, or 50 nm to 1200 nm, or 200 nm to 300 nm, or 300 nm to 400 nm, or 400 nm to 500 nm, or 500 nm to 600 nm, or 600 nm to 700 nm, or 700 nm to 800 nm, or 800 nm to 900 nm, or 900 nm to 1000 nm, or 1000 nm to 1100 nm, or 1100 nm to 1200 nm, or any other suitable range.

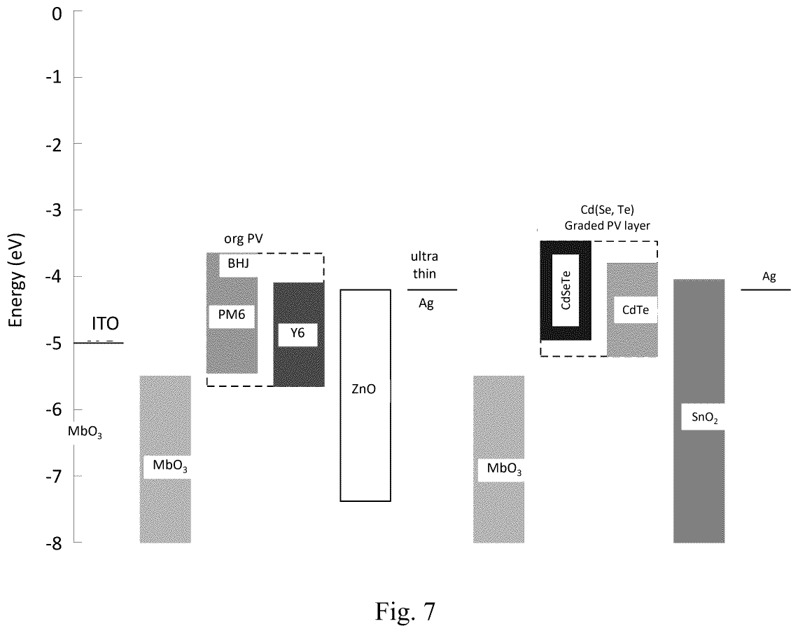

Alternatively, the two sub-cells (303, 304) can be grown on separate glass substrates and stacked. The stacking can be mechanical or via cold-weld bonding of the bottom contacts of the top cell 304 and top contacts of the bottom cell 303. Either configuration (integrated or with separate substrates) can allow for extracting the center contact between sub-cells enabling two terminal (2T), three terminal (3T) and four terminal (4T) contacting configurations, such as described in Forrest, Org Electron, 2020, FIG. 7.14, included herein by reference in its entirety. 3T and 4T configurations eliminate current matching constraints.

Optical reflecting layers 302 can be integrated onto the back surface of the stack to reflect any unabsorbed IR light back into the cell to increase the current of the OPV cell. Current matching can also be achieved by partial absorption of the visible radiation by the OPV using outcoupling optical filters designed for this purpose.

Normal designs for tandem solar cells have light incident on a short wavelength top absorption cell, with the red/NIR absorbing cell positioned underneath, thus closer to the back reflector.

From a manufacturing standpoint for tandem device with OPV 304 and perovskite (or CdTe) sub-cells 303 it is best to place the OPV sub-cell 304 over the perovskite (or CdTe or CIGS) sub-cell 303 so as to not damage the OPV device by processing of the perovskite/CdTe/CIGS cell. To fabricate high performance perovskite cells, one generally anneals the device at Temperatures above 300° C., which will cause catastrophic failure of an organic subcell if the organic subcell were under the perovskite cell at the time of annealing.

Another advantage is that the organic cell may absorb some UV light which would otherwise damage the perovskite cell This is because the high energy UV light can cause bonds to break in the perovskite material generating defects which act as non-radiative recombination sites, accelerating the degradation process, and reducing the efficiency of the device and weakening the stability of the solar cell.

It is desirable for visible light to be absorbed in the perovskite (or CdTe) sub-cell 303 and not in the OPV sub-cell 304, because the perovskite/CdTe sub-cell 303 will produce a higher voltage than the OPV sub-cell 304 for absorbed visible energy photons. The disclosed design therefore combines an OPV 304 which is transparent, semi-transparent, or mostly transparent to visible light, over perovskite (or CdTe) 303, such that NIR is absorbed in the top OPV cell 304 and visible light is absorbed in the bottom perovskite (or CdTe) cell 303. In some embodiments, the OPV 304 is at least 25% transparent to light in the visible spectrum, or at least 30% transparent, or at least 50% transparent, or at least 60% transparent, or at least 70% transparent, or at least 75% transparent, or at least 80% transparent, or at least 85% transparent, or at least 90% transparent, or at least 95% transparent, or at least 97% transparent or at least 98% transparent or at least 99% transparent to light in the visible spectrum, where the visible spectrum may be defined as between 380 nm and 700 nm, or between 400 nm and 700 nm.

FIG. 3 shows schematic of an exemplary tandem PV cell 300. OPV device 300 can be made from vacuum thermal evaporation (VTE) deposited films, sputtered and/or solution processed films. Device 300 can be constructed as a two terminal, a three terminal, or a four terminal device. Device 300 can be made on flexible and light weight substrates such as plastic unlike other devices using crystalline Si as the NIR absorber.

In some embodiments, the tandem solar cell 300 comprises of two or more sub-cells (303, 304) where one or more is organic 304 and one or more is perovskite and/or CdTe 303. In some embodiments, the organic cell 304 is placed closest to incident light (top cell) and absorbs NIR light and transmits visible light through to the bottom perovskite or CdTe cell 303. In some embodiments, this may be the only viable path to achieving greater than 30% PCE thin film PV devices or even greater than 35% PCE thin film PV devices. Thin films between the external electrodes may have any thickness, for example between 300 nm and 3000 nm, or between 300 nm and 2500 nm, or between 300 nm and 2000 nm, or between 500 nm and 1000 nm, or between 300 nm and 1000 nm, or between 500 nm and 2000 nm, or between 300 nm and 1500 nm, or any other suitable thickness.

In some embodiments, the tandem solar cell 300 comprises two or more sub-cells (303, 304) where the sub-cell 304 closest to incident radiation (top cell) absorbs primarily in NIR and bottom sub-cell 303 absorbs primarily in visible.

In some embodiments, the device 300 power conversion efficiency (PCE) is greater than 10%, greater than 15%, greater than 18%, greater than 20%, greater than 25%, or greater than 30%. In some embodiments, the top cell 304 is organic. In some embodiments, the bottom cell 303 is perovskite. In some embodiments, the bottom cell 303 is CdTe, Si, CdSeTe, CIGS, or similar, or any combinations thereof.

In some embodiments, the increased PCE comes from the nature of the tandem device formed using OPV and perovskite cells to absorb different parts of the solar spectrum, with every photon being absorbed in a cell that maximizes the voltage produced by the absorption of that photon-specific efficiencies will depend on the specific chemical composition of the two types of subcells.

In some embodiments, a charge generation layer (CGL) is deposited between the sub-cells (303, 304). In some embodiments, the CGL includes nanoparticles, for example Ag nanoparticles. In some embodiments, other metallic nanoparticles may be used, alternatively or in combination.

In some embodiments, the two or more sub-cells can be grown on separate substrates and then stacked together, for example via cold welding.

In some embodiments, optical reflecting layers 302 can be integrated onto the back surface of the stack. In some embodiments, one or more optical reflecting layers 302 may be textured. The reflecting layers 302 may comprise a regular or substantially regular texture, for example a two-dimensional repeating pattern comprising one or more geometric shapes, for example hemispheres, ovoid sections, or other half polyhedral shapes. In some embodiments, the reflecting layers 302 may have a random texture. In some embodiments, the reflecting layers may have a regular or substantially regular texture in one dimension while having a random texture in the orthogonal dimension.

The one or more reflecting layer 302 may comprise any suitable material, for example silver (Ag), gold, (Au), aluminum, tin, copper, etc. In some embodiments, a textured reflector 302 may comprise a first reflecting layer positioned in contact with substrate 301, which may be smooth, textured, or substantially smooth, and a second transparent layer positioned between the first reflecting layer and the first solar cell 303, where the second transparent layer is independently smooth, textured, or substantially smooth.

Suitable reflectors are highly reflective of both visible and NIR light—and also may in some embodiments be textured to increase the path length of the reflected light to increase absorption. In some embodiments, a reflector is at least 70% reflective, at least 75% reflective, at least 80% reflective, at least 85% reflective, at least 90% reflective, or at least 95% reflective of visible and/or NIR light.

### Combination with Other Materials

The materials described herein as useful for a particular layer in an organic optoelectronic device may be used in combination with a wide variety of other materials present in the device. The materials described or referred to below are non-limiting examples of materials that may be useful in combination with the compounds disclosed herein, and one of skill in the art can readily consult the literature to identify other materials that may be useful in combination.

### Conductivity Dopants

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. The hole-transporting layer can be doped by p-type conductivity dopants and n-type conductivity dopants are used in the electron-transporting layer.

### Experimental Examples

The invention is now described with reference to the following Examples. These Examples are provided for the purpose of illustration only and the invention should in no way be construed as being limited to these Examples, but rather should be construed to encompass any and all variations which become evident as a result of the teaching provided herein.

Without further description, it is believed that one of ordinary skill in the art can, using the preceding description and the following illustrative examples, make and utilize the present invention and practice the claimed methods. The following working examples therefore, specifically point out exemplary embodiments of the present invention, and are not to be construed as limiting in any way the remainder of the disclosure.

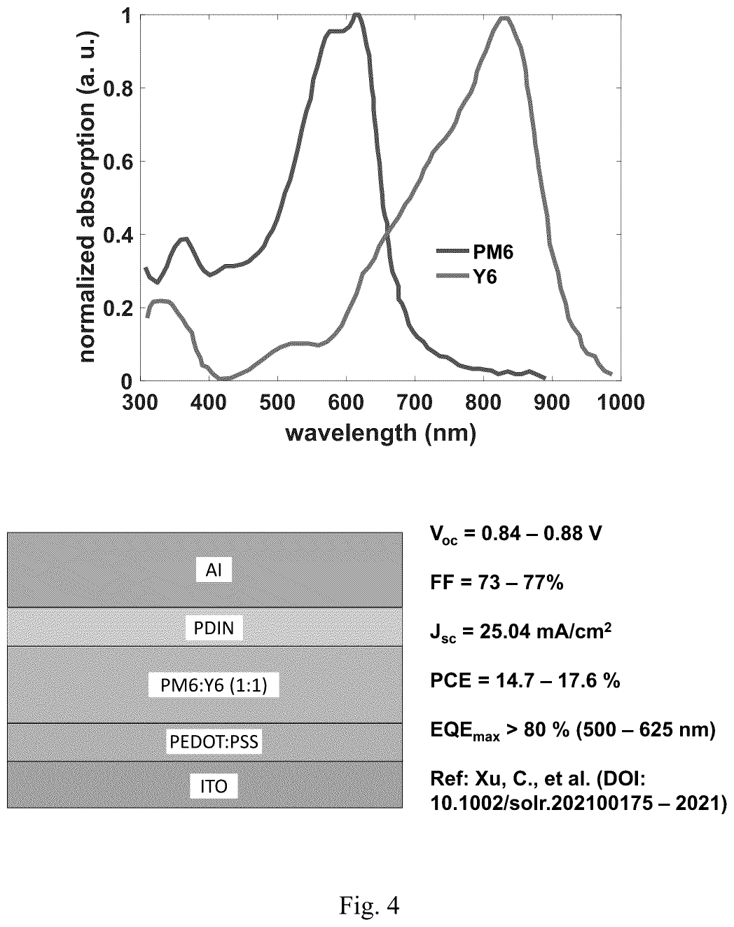

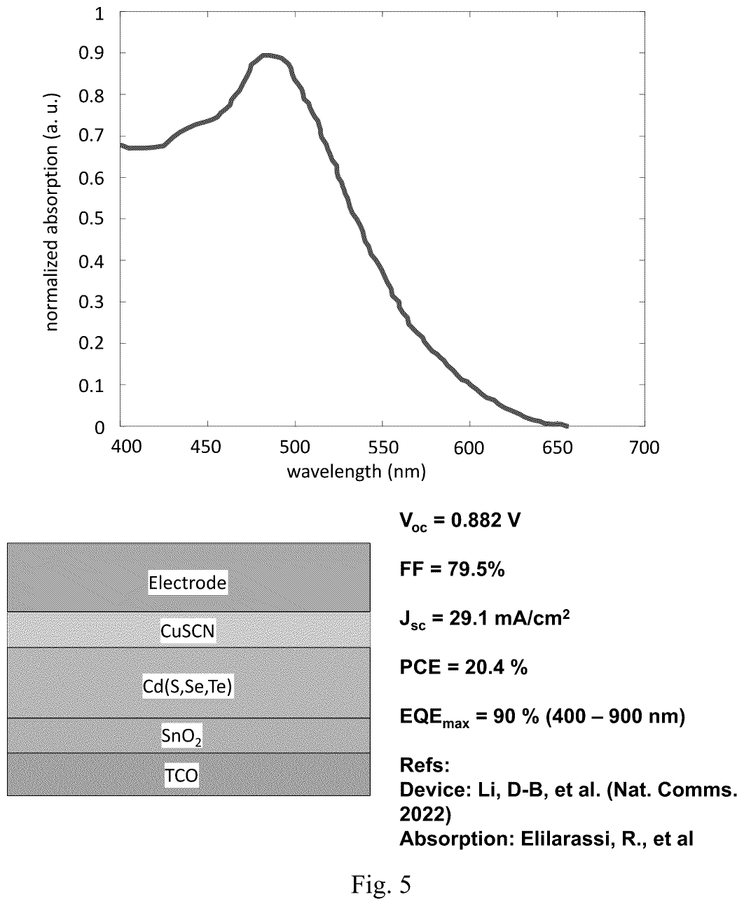

FIG. 4 shows details of a simulation of an organic front cell. FIG. 5 shows details of a simulation of an inorganic back cell.

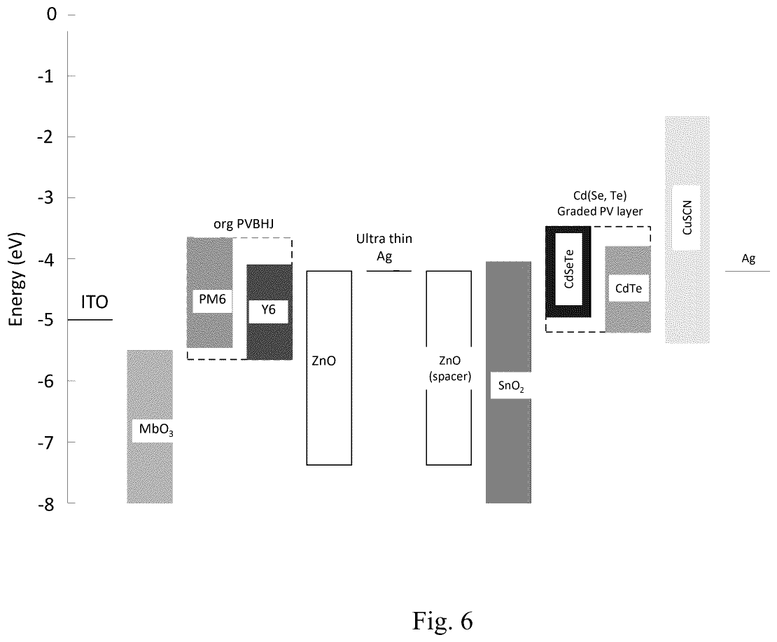

FIG. 6 shows an example device design. Earlier spacer layer PEDOT:PSS presented an energy barrier for charge transport. A ZnO replacement spacer layer may lead to UV emission. A SnO₂ spacer layer may lead to charge imbalance. FIG. 7 shows an example device design.

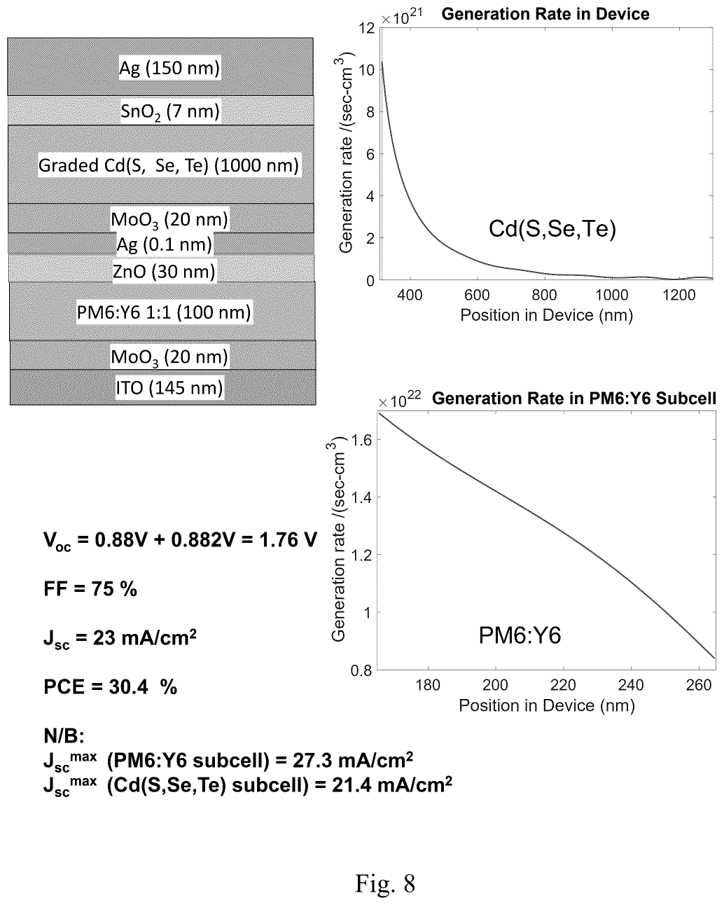

FIG. 8 shows details of a simulation of a hybrid PV device.

### References

The following publications are each hereby incorporated herein by reference in their entirety:
Che, X., Li, Y., Qu, Y. et al. High fabrication yield organic tandem photovoltaics combining vacuum- and solution-processed subcells with 15% efficiency. Nat Energy 3, 422-427 (2018). https://doi.org/10.1038/s41560-018-0134-z
Xu, C., Ma, X., Zhao, Z., Jiang, M., Hu, Z., Gao, J., Deng, Z., Zhou, Z., An, Q., Zhang, J. and Zhang, F. (2021), Over 17.6% Efficiency Organic Photovoltaic Devices with Two Compatible Polymer Donors. Sol. RRL, 5:2100175. https://doi.org/10.1002/solr.202100175
Dangqi Fang, Yaqi Li, Structural, electronic, and optical properties of ZnO:ZnSnN2 compounds for optoelectronics and photocatalyst applications, Physics Letters A, Volume 384, Issue 26, 2020, 126670, ISSN 0375-9601, https://doi.org/10.1016/j.physleta.2020.126670.
Dai, X.; Koshy, P.; Sorrell, C. C.; Lim, J.; Yun, J. S. Focussed Review of Utilization of Graphene-Based Materials in Electron Transport Layer in Halide Perovskite Solar Cells: Materials-Based Issues. Energies 2020, 13, 6335. https://doi.org/10.3390/en13236335
Chayanit Wechwithayakhlung, Suttipong Wannapaiboon, Sutassana Na-Phattalung, Phisut Narabadeesuphakorn, Similan Tanjindaprateep, Saran Waiprasoet, Thidarat Imyen, Satoshi Horike, and Pichaya Pattanasattayavong Inorganic Chemistry 2021 60 (21), 16149-16159, DOI:10.1021/acs.inorgchem. 1c01813
Shah, A., Pandey, R., Nicholson, A., Lustig, Z., Abbas, A., Danielson, A., Walls, J., Munshi, A. and Sampath, W. (2021), Understanding the Role of CdTe in Polycrystalline CdSe x Tel-x/CdTe-Graded Bilayer Photovoltaic Devices. Sol. RRL, 5:2100523. https://doi.org/10.1002/solr.202100523
Stephen Forrest, Organic Electronics: Foundations to Applications, Oxford University Press, 2020

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention. The appended claims are intended to be construed to include all such embodiments and equivalent variations.

What is claimed is:

1. A tandem photovoltaic (PV) device, comprising:
a substrate;
a reflector layer on one side of the substrate;
a first PV sub-cell in optical communication with the reflector layer, configured to absorb visible light; and
a second PV sub-cell above the first PV sub-cell, configured to absorb NIR light.

2. The device of claim 1, wherein the first PV sub-cell comprises a perovskite sub-cell, a CdTe sub-cell, a Si sub-cell, a CdSeTe sub-cell, or a CIGS sub-cell.

3. The device of claim 1, wherein the second PV sub-cell comprises an organic sub-cell.

4. The device of claim 3, wherein the second PV sub-cell is at least 30% transparent across the visible spectrum or at least 50% transparent across the visible spectrum.

5. The device of claim 1, further comprising a charge generation layer (CGL) between the first and second PV sub-cells.

6. The device of claim 4, wherein the CGL comprises Ag nanoparticles.

7. The device of claim 1, wherein the device has a power conversion efficiency (PCE) greater than 30% or greater than 35%.

8. The device of claim 1, wherein the device comprises vacuum thermal evaporation (VTE) deposited films.

9. The device of claim 1, wherein the device comprises solution processed films.

10. The device of claim 1, wherein the first PV sub-cell comprises two or more PV sub-cells.

11. The device of claim 1, wherein the second PV sub-cell comprises two or more PV sub-cells.

12. The device of claim 1, wherein the device comprises a two terminal (2T), a three terminal (3T), or a four terminal (4T) device.

13. The device of claim 1, wherein the device is flexible.

14. The device of claim 1, wherein the reflector layer is configured to reflect NIR light or visible light.

15. A product comprising the device of claim 1, the product selected from the group consisting of: a display screen, a discrete light source, a lighting panel, a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video wall comprising multiple displays tiled together, a theater or stadium screen, a sign, an electronic component module, a lighting panel, a solar cell, a light weight solar cell, a flexible solar cell, a solar cell integrated with thin film electronics, a thin film power supply, a solar farm, a sensor, a radio receiver/transmitter, an audio producing device, a computing device, an IT device, a shelf label, a window, a wall, and a roof.
